(19) United States
(12) Patent Application Publication
(10) Pub. No.: US 2016/0258988 A1
(43) Pub. Date: Sep. 8, 2016

(54) SEMICONDUCTOR DEVICE AND ELECTRIC ENERGY METER

(71) Applicant: Kabushiki Kaisha Toshiba, Tokyo (JP)

(72) Inventors: Masakazu Yaginuma, Yokosuka Kanagawa (JP); Junichi Takeda, Yokohama Kanagawa (JP); Masanori Matsuda, Tokyo (JP)

(21) Appl. No.: 14/841,900

(22) Filed: Sep. 1, 2015

(30) Foreign Application Priority Data
Mar. 6, 2015 (JP) 2015-044672

(51) Int. Cl. G01R 21/06

(52) U.S. Cl. CPC G01R 21/06

(57) ABSTRACT

According to one embodiment, there is provided a semiconductor device. The semiconductor device includes a metering unit that operates under control of a first processor to measure electric power consumed, a communication unit that operates under the control of a second processor different from the first processor to perform communication, and a path connecting the metering unit and the communication unit.

### CROSS-REFERENCE TO RELATED APPLICATIONS

This application is based upon and claims the benefit of priority from Japanese Patent Application No. 2015-044672, filed Mar. 6, 2015, the entire contents of which are incorporated herein by reference.

### FIELD

Embodiments described herein relate generally to a semiconductor device and an electric energy meter.

### BACKGROUND

The smart meter, which can automatically perform meter reading and display the power consuming state, is now being used in increasing numbers as a next-generation electric energy meter that differs from the analog induction-type electric energy meter hitherto used. The smart meter includes a metering board holding a metering unit that measures, as a digital value, the electric power used in a power consumer's house. The smart meter further includes a communication board holding a communication unit that transmits the data representing the power consumption measured by the metering unit, to the power company or the like, and communicates with the system that controls the energy consumption in the power consumer's house.

### BRIEF DESCRIPTION OF THE DRAWINGS

FIG. 1 is a diagram showing a schematic configuration common to the smart meters (electric energy meters) according to the embodiments;

FIG. 2 is a diagram showing a schematic configuration of the integrated circuit incorporated in a semiconductor device according to the first embodiment;

FIG. 3 is a sequence diagram showing an exemplary operation performed when the communication unit requests the metering unit to transmit the data in the first embodiment;

FIG. 4 is a sequence diagram showing an exemplary operation performed when the communication unit requests the metering unit to update the program in the first embodiment;

FIG. 5 is a diagram showing a schematic configuration of the integrated circuit incorporated in a semiconductor device according to the second embodiment;

FIG. 6 is a sequence diagram showing an exemplary operation performed when the communication unit requests the metering unit to transmit the data in the second embodiment; and

FIG. 7 is a sequence diagram showing an exemplary operation performed when the communication unit requests the metering unit to update the program in the second embodiment.

### DETAILED DESCRIPTION

In general, according to one embodiment, there is provided a semiconductor device. The semiconductor device includes a metering unit that operates under control of a first processor to measure electric power consumed, a communication unit that operates under the control of a second processor different from the first processor to perform communication, and a path connecting the metering unit and the communication unit.

Embodiments will be described with reference to the accompanying drawings. In the following description, any components that perform the same function and have the same structure are identified with the same reference number.

Any meter used in transactions, such as an electric energy meter, should guarantee appropriate values to be measured, and is thus obliged to be examined for structure and performance, as is stipulated in the Measurement Law. Particularly, the metering unit is an important portion which processes the data read from the meter and the data related to accounting. Accordingly, the metering unit is required to have robustness to prevent software alteration and data reading by an unauthorized access from outside.

Further, in the smart meter, it is required to utilize the function of the communication unit to supply an updated program from outside so that functions of the software of the metering unit may be expanded and bugs in the software of the metering unit are worked out to impart availability to the smart meter.

In addition to the above-mentioned two requirements, i.e., robustness and availability, the smart meter is also required to accomplish rightsizing, particularly downsizing, which is accomplished by consolidating the metering unit held on the metering board and the communication unit held on the communication board. If these two units are consolidated, however, the metering unit may become less independent of the communication unit, possibly impairing the robustness of the metering unit. On the other hand, when the robustness of the metering unit is increased too much, however, the smart meter may be impaired in terms of availability.

The embodiments described below can achieve rightsizing, while maintaining both robustness and availability.

### Items Common to the Embodiments

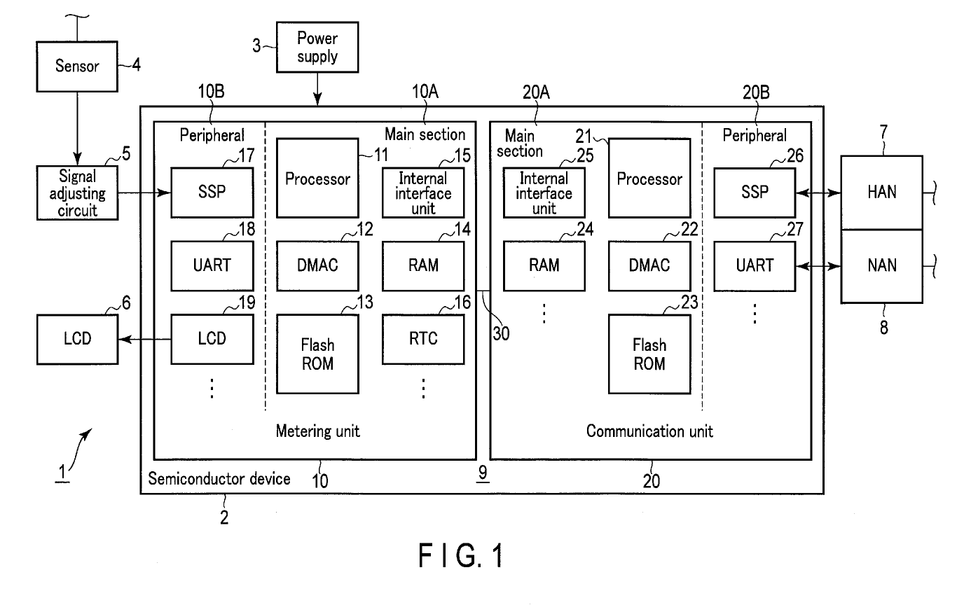

FIG. 1 is a diagram showing the schematic configuration common to the smart meters (electric energy meters) according to the embodiments.

The smart meter (electric energy meter) 1 shown in FIG. 1 includes a semiconductor device 2, a power supply 3, a sensor 4, a signal adjusting circuit 5, a liquid crystal display (LCD) 6, a home area network (HAN) communication device 7, and a neighborhood area network (NAN) communication device 8.

The semiconductor device 2 is one-chip device in which an integrated circuit (IC) 9 is sealed in a package. The device 2 has a seal showing that the device 2 has been examined for structure and performance as stipulated in the Measurement Law and has passed the examination.

The integrated circuit 9 includes a metering unit 10 that measures the electric power used in a power consumer's house, and a communication unit 20 that performs communication with any device outside the semiconductor device 2. The metering unit 10 and the communication unit 20 are incorporated in the one-chip semiconductor device 2, but are controlled by independent processors, respectively. All or some of various functions of each of the metering unit 10 and the communication unit 20 may be implemented in a form of a program executed by a processor. The metering unit 10 and the communication unit 20 are independently arranged, but are configured to use a common power supply and a common clock signal in the integrated circuit 9. Nonetheless, they may use different power supplies and different clock signals.

The integrated circuit 9 further includes a path (intra-chip wire) 30 connecting the metering unit 10 and the communication unit 20. The path 30 includes a transmission line that transmits commands between the metering unit 10 and the communication unit 20 and transmits data between the metering unit 10 and the communication unit 20. The metering unit 10 also performs a control to receive only those of the requests transmitted to it from the communication unit 20 via the path 30, which satisfy a prescribed condition. Further, the metering unit 10 records any request coming from the communication unit 20 and found not appropriate as an error log in a prescribed memory area (e.g., memory area of an external memory device connected to the interface provided in the metering unit 10), and does not respond to the communication unit 20. The cause of an unauthorized access and the like can be determined by reading and analyzing the error log.

The power supply 3 supplies power for driving both the metering unit 10 and the communication unit 20.

The sensor 4 detects the current and voltage of the electric power used in the power consumer's house, and outputs analog signals representing the current and voltage.

The signal adjusting circuit 5 is equivalent to, for example, an analog front end (AFE) circuit. The signal adjusting circuit 5 includes an amplifier for amplifying the analog signals, a filter for reducing noise, and an analog-to-digital (A/D) converter for converting an analog signal to a digital signal. The signal adjusting circuit 5 converts the analog signal supplied from the sensor 4 to a digital signal that the metering unit 10 can process, then adjusts the digital signal, and outputs the digital signal to the metering unit 10.

The LCD 6 displays the information, such as the power consumed, supplied from the metering unit 10.

The HAN communication device 7 performs communication with a home energy and energy management system (HEMS) or with an in-home display (IHD) that displays the power consuming state.

The NAN communication device 8 is connected to the communication network of the power company, transmits various information items (including power consumption data) to the power company, and receives various information items from the power company.

The metering unit 10 has a main section 10A. The main section 10A includes a processor 11, a direct memory access controller (DMAC) 12, a flash read-only memory (ROM) 13, a random access memory (RAM) 14, an internal interface unit 15, and a real time clock (RTC) 16. The metering unit 10 further has a peripheral 10B. The peripheral 10B includes a synchronous serial port (SSP) interface unit 17, a universal asynchronous receiver-transmitter (UART) interface unit 18, and an LCD interface unit 19.

The processor 11 controls overall operations of components in the metering unit 10, and is independent of the communication unit 20. The processor 11 executes the program stored in the flash ROM 13, performing various controls. The processor 11 uses, for example, the memory area of the RAM 14 as a work area, and performs various processes, calculating the power consumption (or accounting value) and calculating the accumulated power consumption from the digital current-voltage data supplied from the signal adjusting circuit 5 via the SSP interface unit 17. Further, the processor 11 stores the various information items including the result of measurement in a prescribed memory area (e.g., flash ROM 13), and causes the LCD 6 to display the information supplied via the LCD interface unit 19. The processor 11 further transmits the information to the communication unit 20, first through the UART interface unit 18 or internal interface unit 15 and then through the path 30. Still further, the processor 11 determines whether the request (e.g., command) is appropriate or not, and performs a process in accordance with the result of determination.

When the processor 11 instructs the DMAC 12 to transfer data, the DMAC 12 transfers the data between the memories such as the flash ROM 13 and the RAM 14 or between the memories and an I/O device, not through the processor 11.

The flash ROM 13 stores one or more programs the processor 11 may execute.

The RAM 14 provides a work area the processor 11 may use to perform various controls.

The internal interface unit 15 is an interface dedicated to the data transmission between the metering unit 10 and the communication unit 20. For example, the internal interface unit 15 performs communication with the internal interface 25 incorporated in the communication unit 20, and can transmit data in a parallel transmission scheme, under a prescribed condition, between the metering unit 10 and the communication unit 20. The internal interface units 15 and 25 are not absolutely necessary. In place of the internal interface units 15 and 25, the UART interface units 18 and 27, both later described, may be used to achieve the communication between the metering unit 10 and the communication unit 20. In this embodiment, the parallel transmission scheme is used, transmitting data between the internal interface units 15 and 25. The transmission scheme is not limited to the parallel transmission scheme, nevertheless. Any other scheme, such as serial transmission scheme, may be utilized.

The RTC 16 generates a clock signal that is used in both the metering unit 10 and the communication unit 20.

The SSP interface unit 17 has both a serial peripheral interface (SPI) function and an inter-IC communication (I²C) interface function. In this embodiment, the SSP interface unit 17 performs the SPI interface function. The SPI interface function of the SSP interface unit 17 is an interface function based on the SPI specification, and can perform communication with any other SPI interface function based on the SPI specification. For example, the SPI interface function of the SSP interface unit 17 can perform communication with the SPI interface function provided in the signal adjusting circuit 5. The digital current data and digital voltage data serial-transmitted from the signal adjusting circuit 5 can therefore be acquired in the main section 10A.

The UART interface unit 18 is an interface function based on the DART specification, and can perform communication with any other DART interface function based on the DART specification. For example, the DART interface unit 18 can perform communication with the DART interface unit 27 provided in the communication unit 20. Data can therefore be serial-transmitted, under a prescribed condition, between the metering unit 10 and the communication unit 20.

The LCD interface unit 19 is an interface that enables the LCD 6 to display the power-amount information supplied from the main section 10A of the metering unit 10.

The communication unit 20 has a main section 20A. The main section 20A includes a processor 21, a DMAC 22, a flash ROM 23, a RAM 24, and an internal interface unit 25. The communication unit 20 further has a peripheral 20B. The peripheral 20B includes an SSP interface unit 26 and an UART interface unit 27.

The processor 21 controls overall operations of components in the communication unit 20, and is independent of the metering unit 10. The processor 21 executes the programs stored in the flash ROM 23, performing various controls. The processor 21 uses, for example, the memory area of the RAM 24 as a work area, transmitting the various information items acquired via the HAN communication device 7 or the NAN communication device 8, to the metering unit 10 under a prescribed condition, first through the UART interface unit 27 or internal interface unit 25 and then through the path 30. Further, the processor 21 receives, under a prescribed condition, various information items transmitted from the metering unit 10 first through the path 30 and then through the UART interface unit 27 or internal interface unit 25. The processor 21 then transmits, under a prescribed condition, the information items to an external network through the HAN communication device 7 or the NAN communication device 8.

If instructed by the processor 21 to transfer data, the DMAC 22 transfers data between the memories such as flash ROM 23 and RAM 24 or between the memories and an I/O device, not through the processor 21.

The flash ROM 23 stores one or more programs the processor 21 may execute.

The RAM 24 provides a work area the processor 21 may use to perform various controls.

Like the internal interface unit 15 described above, the internal interface unit 25 is an interface function dedicated to the data transmission between the metering unit 10 and the communication unit 20. For example, the internal interface unit 25 performs communication with the internal interface 15 incorporated in the communication unit 10, and can transmit data in a parallel transmission scheme, under a prescribed condition, between the metering unit 10 and the communication unit 20.

Like the SSP interface unit 17 described above, the SSP interface unit 26 has both the SPI interface function and the I²C interface function. In this embodiment, the SSP interface unit 26 performs the SPI interface function. The SPI interface function of the SSP interface unit 26 is an interface function based on the SPI specification, and can perform communication with any other SPI interface function based on the SPI specification. For example, the SPI interface function of the SSP interface unit 26 can perform communication with the SPI interface function provided in the HAN communication device 7 or the NAN communication device 8. Various information items can therefore be sent from the main section 20A to the HAN communication device 7 or the NAN communication device 8.

Like the UART interface unit 18 described above, the UART interface unit 27 is an interface function based on the UART specification, and can perform communication with any other UART interface function based on the DART specification. For example, the DART interface unit 18 can perform communication with the DART interface unit 27 provided in the communication unit 20. Data can therefore be serial-transmitted, under a prescribed condition, between the metering unit 10 and the communication unit 20.

As practical methods for implementing the path 30, embodiments will provide at least two configurations. In a first configuration, the UART interface units 18 and 27 provided respectively in the metering unit 10 and communication unit 20 are configured to be able to perform communication with each other. In a second configuration, the internal interfaces 15 and 25 provided respectively in metering unit 10 and communication unit 20 are configured to be able to communicate with each other. Two practical methods will be explained below in detail through first and second embodiments.

### First Embodiment

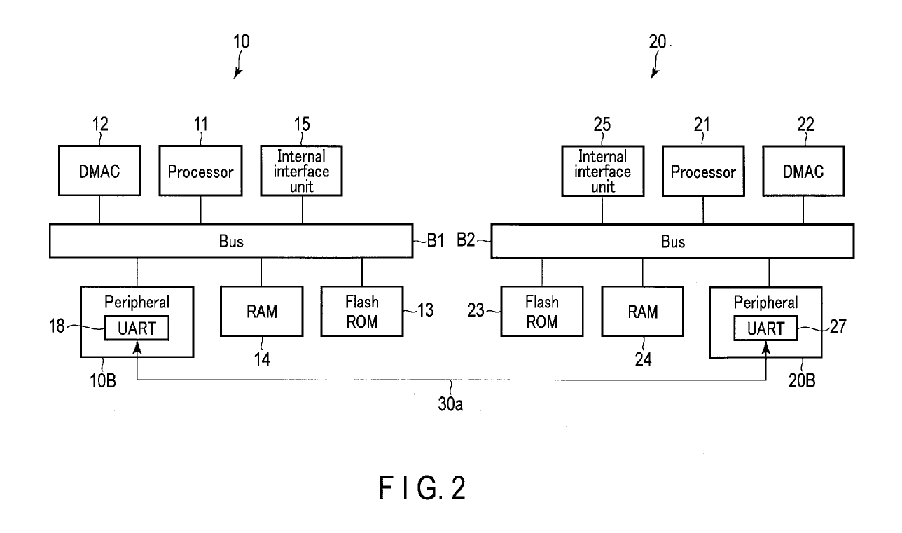

The configuration and operation of the integrated circuit 9 incorporated in the semiconductor device 2 according to the first embodiment will be described with reference to FIG. 1 and FIGS. 2 to 4. The components identical to those shown in FIG. 1 are designated by the same reference numbers in FIGS. 2 to 4, and will not be repeatedly described.

FIG. 2 is a diagram showing a schematic configuration of the integrated circuit 9 incorporated in the semiconductor device 2 according to the first embodiment. In FIG. 2, some of the components shown in FIG. 1 are not illustrated, facilitating an understanding of the features of the integrated circuit 9.

In the first embodiment, the path 30 is a serial transmission line 30a based on the UART specification. The serial transmission line 30a connects the UART interface unit 18 provided in the peripheral 10B of the metering unit 10 to the UART interface unit 27 provided in the peripheral 20B of the communication unit 20.

In the metering unit 10, the processor 11, the DMAC 12, flash ROM 13, RAM 14, internal interface unit 15 and UART interface unit 18 (provided in the peripheral 10B) are connected by an internal bus B1. Similarly, in the communication unit 20, the processor 21, DMAC 22, flash ROM 23, RAM 24, internal interface unit 25 and UART interface unit 27 (provided in the peripheral 20B) are connected by an internal bus B2 different from the internal bus B1 provided in the metering unit 10. The internal bus B1 and the internal bus B2 are completely isolated.

In this configuration, a request (e.g., command) may be sent from the communication unit 20 to the metering unit 10 via the serial transmission line 30a. In this case, the processor 11 in metering unit 10 collates the information stored in a prescribed memory area (e.g., flash ROM 13), determining whether the request is appropriate or not. The processor 11 can therefore perform an appropriate process that accords with the result of determination. Two exemplary operations will be explained.

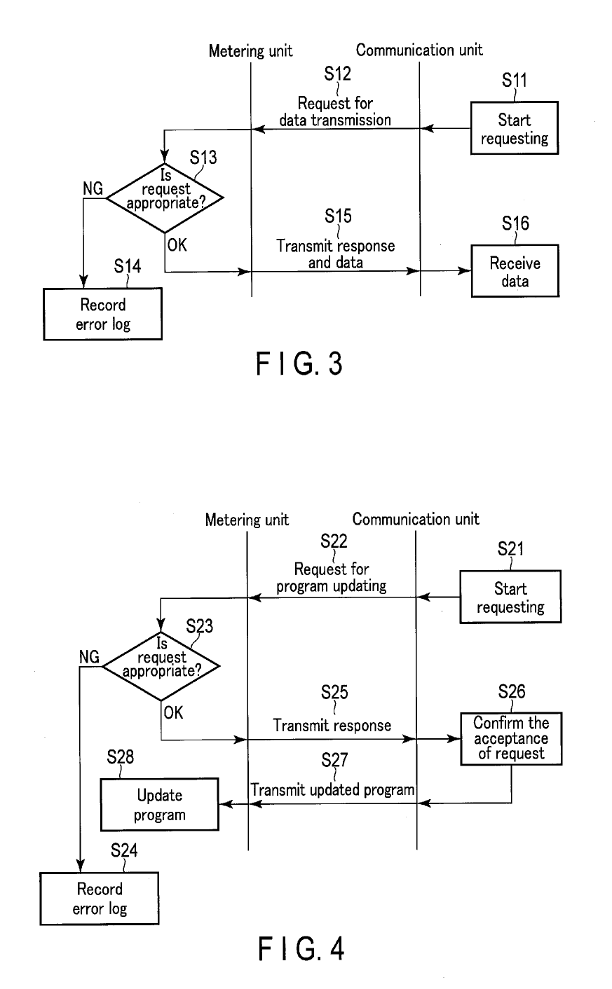

The first exemplary operation, which is performed when the metering unit 10 receives a data transmission request from the communication unit 20, will be explained with reference to the sequence diagram of FIG. 3.

Assume that the communication unit 20 requests, at regular intervals, the metering unit 10 to transmit the data representing the accumulated power consumption.

Before making the request for data transmission, an interruption request is made and a response to this request is made, though not described here.

At a prescribed time, the communication unit 20 starts requesting the metering unit 10 to transmit the power consumption data (Step S11). The communication unit 20 sends, for example, a prescribed command added with an authentication key, to the metering unit 10 via the serial transmission line 30a. The communication unit 20 thus requests the metering unit 10 to transmit the power consumption data (Step S12).

The metering unit 10 receives the request for transmitting the power consumption data, and determines whether the request is appropriate or not (Step S13). The metering unit 10 collates the command and authentication key, both sent from the communication unit 20, with the information stored in the prescribed memory area (e.g., flash ROM 13) and representing a proper combination of the prescribed command and the authentication key. That is, the metering unit 10 determines whether the command and authentication key are identical to the information, thus determining whether the request is appropriate or not.

When the processor 11 determines that the request is not appropriate (NG in Step S13), it records, in a prescribed memory area, the information representing the time of making an error and the command/authentication key that has caused the error (Step S14), and does not respond to the communication unit 20. The cause of an unauthorized access and the like can be determined by reading and analyzing the error log.

When the metering unit 10 determines that the request is appropriate (OK in Step S13), it transmits a response showing the acceptance of the request and the power consumption data requested to the communication unit 20 through the serial transmission line 30a (Step S15).

The communication unit 20 receives the response and the power consumption data, both transmitted from the metering unit 10 (Step S16).

The sequence of the first exemplary operation is thus completed.

The second exemplary operation, which is performed when the metering unit 10 receives a program updating request from the communication unit 20, will be explained with reference to the sequence diagram of FIG. 4.

Assume that the communication unit 20 requests the metering unit 10 to update the program used in the metering unit 10 in order to expand functions of the software of the metering unit 10 or work out bugs in the software of the metering unit 10. Before making the request for program updating, an interruption request is made and a response to this request is made, though not described here.

On receiving a program updating request from the request source via the HAN communication device 7 or the NAN communication device 8, the communication unit 20 starts requesting the metering unit 10 to update the program (Step S21). The communication unit 20 sends a prescribed command added with an authentication key, to the metering unit 10 via the serial transmission line 30a. The communication unit 20 thus requests the metering unit 10 to update the program (Step S22).

The metering unit 10 receives the request for updating the program, and determines whether the request is appropriate or not (Step S23). The metering unit 10 collates, for example, the command and authentication key, both sent from the communication unit 20, with the information stored in the prescribed memory area (e.g., flash ROM 13) and representing a proper combination of the prescribed command and the authentication key. That is, the metering unit 10 determines whether the request is appropriate or not.

When the metering unit 10 determines that the request is not appropriate (NG in Step S23), it records, in a prescribed memory area, the information representing the time of making an error and the command/authentication key that has caused the error (Step S24), and does not respond to the communication unit 20. The cause of an unauthorized access and the like can be determined by reading and analyzing the error log.

When the metering unit 10 determines that the request is appropriate (OK in Step S23), a response showing the acceptance of the request is transmitted to the communication unit 20 via the serial transmission line 30a (Step S25).

The communication unit 20 receives the response sent from the metering unit 10, confirming that the request has been accepted (Step S26). Then, the communication unit 20 transmits the updated program provided by the program-updating request source, via the serial transmission line 30a of the metering unit 10 (Step S27).

On receiving the updated program from the communication unit 20, the metering unit 10 uses the updated program, updating the program being used at present (Step S28).

The sequence of the second exemplary operation is thus completed.

In the first embodiment, it is possible to expand functions of the software on the metering unit 10 and work out bugs in the software of the metering unit 10, while preventing the data reading and software alteration due to an unauthorized access to the metering unit 10 from outside, and also possible to downsize the smart meter, without impairing the robustness and availability of the smart meter.

In the first embodiment, both the metering unit 10 and the communication unit 20 are incorporated in the integrated circuit 9 that is sealed in one chip. The smart meter can therefore be made much smaller than the conventional meter in which the metering unit and communication unit are mounted on two boards, respectively.

In the first embodiment, it is possible to realize a manufacturing mode in which a sole chip maker makes a chip, unlike the conventional manufacturing mode in which boards, units and connectors are respectively manufactured by different manufacturers. Accordingly, the smart meter hardly malfunctions due to, if any, the design mismatching between the measuring and communication units, and can be manufactured in a short time.

In the first embodiment, the metering unit 10 and communication unit 20 are incorporated in one integrated circuit 9 and use common resources (e.g., one power supply and one clock signal). Accordingly, the mismatching between the metering unit 10 and the communication unit 20 can hardly take place.

In the first embodiment, the path 30 (e.g., serial transmission line 30a) connecting the metering unit 10 and communication unit 20 is an in-chip line, which is greatly different from the connecting mode in which the measuring board and communication board are connected via a lead line or another board in a conventional smart manner. The path 30 can therefore be extremely short, which helps to reduce the noise in the signal to a minimum. Moreover, the path 30 can transmit important data for use in meter reading and charge power accounting, without impairing the data reliability.

In the first embodiment, the path 30 (e.g., serial transmission line 30a) connecting the metering unit 10 and communication unit 20 is realized by using an existing versatile interface. This can reduce the increase in the designing cost and manufacturing cost of the smart meter.

As specified above, the metering unit 10 and the communication unit 20 are incorporated in a one-chip semiconductor device, but are controlled by two independent processors, respectively. Therefore, they interfere with each other no more than is necessary. That is, they exchange a specific data item only. This can prevent data rewriting, and can guarantee the reliability of the power consumption measured.

Further, since the internal bus B1 of the metering unit 10 and the internal bus B2 provided in the communication unit 20 is completely isolated, the data is never exchanged between the metering unit 10 and the communication unit 20 through the internal buses B1, B2. The data is exchanged though the path 30 only. This can guarantee the independence of the metering unit 10.

### Second Embodiment

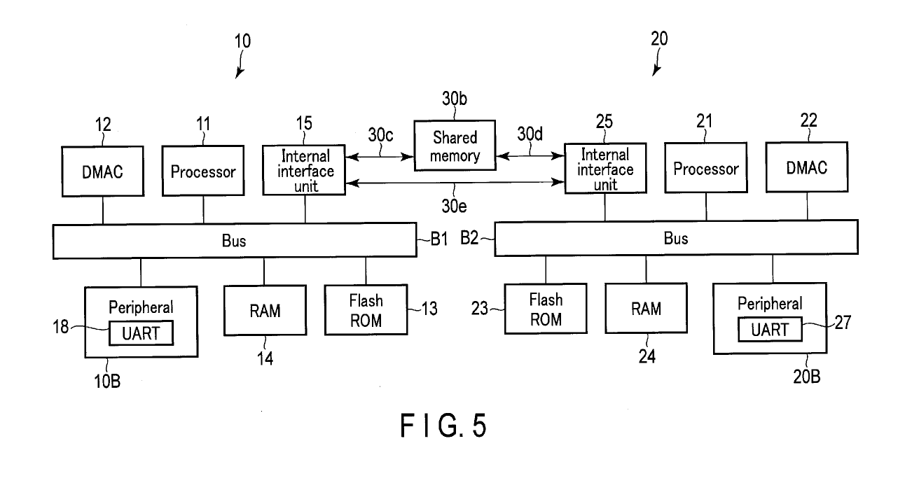

The configuration and operation of the integrated circuit 9 incorporated in the semiconductor device 2 according to the second embodiment will be described with reference to FIG. 1 and FIGS. 5 to 7. The components identical to those of the first embodiment are designated by the same reference numbers in FIGS. 5 to 7, and will not be repeatedly described.

FIG. 5 is a diagram showing a schematic configuration of the integrated circuit 9 incorporated in the semiconductor device 2 according to the second embodiment. Some of the components identical to those described with reference to FIG. 1 are not illustrated in FIG. 5, facilitating an understanding of the features of the integrated circuit 9.

In the second embodiment, as an example for the path 30, there is provided a dedicated path that is dedicated to the data transmission between the metering unit 10 and the communication unit 20. The dedicated path connects the internal interface unit 15 of the metering unit 10 and the internal interface unit 25 of the communication unit 20. The dedicated path includes a shared memory 30b, parallel transmission lines 30c and 30d, and an interruption line 30e.

The shared memory 30b is a memory, in and from which the metering unit 10 and communication unit 20 can write and read data through the parallel transmission lines 30c and 30d. Data is transmitted between the metering unit 10 and the communication unit 20 after it has been written in, and read from, the shared memory 30b.

The parallel transmission line 30c is provided to achieve parallel data transmission between the internal interface unit 15 provided in the metering unit 10 and the shared memory 30b.

The parallel transmission line 30d is a line for achieving the parallel data transmission between the internal interface unit 25 provided in the communication unit 20 and the shared memory 30b

The interruption line 30e is a line for transmitting an interruption signal prompting a communication partner to read information, if any is written, from the shared memory 30b.

In this configuration, the processor 11 provided in the metering unit 10 detects an interruption signal transmitted from, for example, the communication unit 20 through the interruption line 30e. The processor 11 then reads the information that the communication unit 20 has written from the shared memory 30b. If a request (i.e., command or the like) is acquired from the information, the processor 11 collates the request with the information stored in the memory area (e.g., flash ROM 13), thereby determining whether the request is appropriate or not. Hence, the processor 11 can perform an appropriate process that accords with the result of determination. Two exemplary operations will be explained.

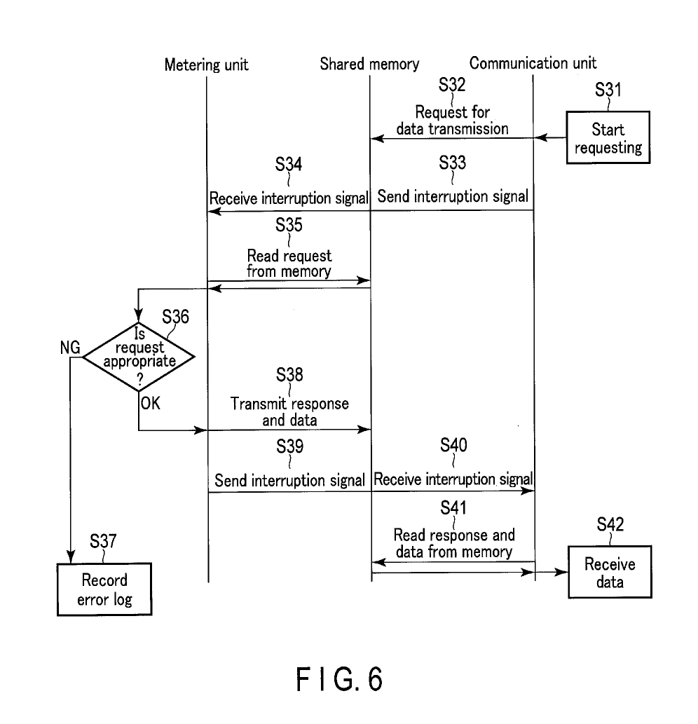

The first exemplary operation, which is performed when the metering unit 10 receives a data transmission request from the communication unit 20, will be explained with reference to the sequence diagram of FIG. 6.

Assume that the communication unit 20 requests, at regular intervals, the metering unit 10 to transmit the data representing the accumulated power consumption.

At a prescribed time, the communication unit 20 starts requesting the metering unit 10 to transmit the power consumption data (Step S31). The communication unit 20 sends, for example, a prescribed command added with an authentication key, to the metering unit 10 via the shared memory 30b. The communication unit 20 thus requests the metering unit 10 to transmit the power consumption data. More specifically, the communication unit 20 writes information representing the request for the transmission of the power consumption data, in the shared memory 30b through the parallel transmission line 30d (Step S32). Then, the communication unit 20 sends an interruption signal to the metering unit 10 through the interruption line 30e, prompting the metering unit 10 to read the information stored in the shared memory 30b (Step S33).

The metering unit 10 receives the interruption signal sent via the interruption line 30e (Step S34). Then, the metering unit 10 reads the information requesting the transmission of the power consumption data, from the shared memory 30b through the parallel transmission line 30c (Step S35).

On receiving the information requesting the transmission of the power consumption data, the metering unit 10 determines whether the request is appropriate or not (Step S36). More specifically, the metering unit 10 collates the command and authentication key, both sent from the communication unit 20, with the information stored in the prescribed memory area (e.g., flash ROM 13) and representing a proper combination of the prescribed command and the authentication key. That is, the metering unit 10 determines whether the request is appropriate or not.

When the metering unit 10 determines that the request is not appropriate (NG in Step S36), it records, in a prescribed memory area, the information representing the time of making an error and the command/authentication key that has caused the error (Step S37), and does not respond to the communication unit 20. The cause of an unauthorized access and the like can be determined by reading and analyzing the error log.

When the metering unit 10 determines that the request is appropriate (OK in Step S36), it transmits the power consumption data to the communication unit 20 via the shared memory 30b, together with a response showing the acceptance of the request. More specifically, the metering unit 10 transmit the response showing the acceptance of the request and the power consumption data requested, to the shared memory 30b through the parallel transmission line 30c (Step S38). Then, the metering unit 10 sends an interruption signal to the communication unit 20 via the interruption line 30e, prompting the communication unit 20 to read the information stored in the shared memory 30b (Step S39).

The communication unit 20 receives the interruption signal sent via the interruption line 30e (Step S40). Then, the communication unit 20 reads the response and power consumption data from the shared memory 30b (Step S41), and receives response and power consumption data (Step S42).

The sequence of the first exemplary operation is thus completed.

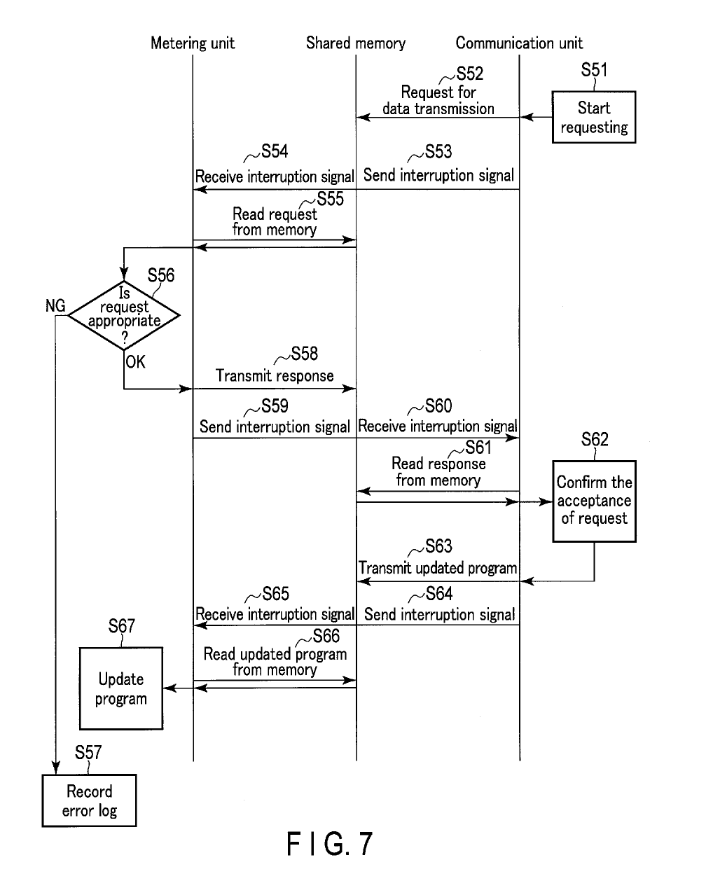

The second exemplary operation, which is performed when the metering unit 10 receives a program updating request from the communication unit 20, will be explained with reference to the sequence diagram of FIG. 7.

Assume that the communication unit 20 requests the metering unit 10 to update the program used in the metering unit 10 in order to expand functions of the software or work out bugs in the software of the metering unit 10.

On receiving a program updating request from the request source via the HAN communication device 7 or the NAN communication device 8, the communication unit 20 starts requesting the metering unit 10 to update the program (Step S51). The communication unit 20 sends a prescribed command added with an authentication key, to the metering unit 10 via the shared memory 30b. The communication unit 20 thus requests the metering unit 10 to update the program. More specifically, the communication unit 20 writes information representing the request for updating the program, in the shared memory 30b through the parallel transmission line 30d (Step S52). Then, the communication unit 20 sends an interruption signal to the metering unit 10 through the interruption line 30e, prompting the metering unit 10 to read the information stored in the shared memory 30b (Step S53).

The metering unit 10 receives the interruption signal sent via the interruption line 30e (Step S54). Then, the metering unit 10 reads the information requesting program updating from the shared memory 30b through the parallel transmission line 30c (Step S55).

On receiving the information requesting the program updating, the metering unit 10 determines whether the request is appropriate or not (Step S56). For example, the metering unit 10 collates the command and authentication key, both sent from the communication unit 20, with the information stored in the prescribed memory area (e.g., flash ROM 13) and representing a proper combination of the prescribed command and the authentication key. That is, the metering unit 10 determines whether the request is appropriate or not.

When the metering unit 10 determines that the request is not appropriate (NG in Step S56), it records, in a prescribed memory area, the information representing the time of making an error and the command/authentication key that has caused the error (Step S57), and does not respond to the communication unit 20. The cause of an unauthorized access and the like can be determined by reading and analyzing the error log.

When the metering unit 10 determines that the request is appropriate (OK in Step S56), it transmits a response showing the acceptance of the request, to the communication unit 20 via the shared memory 30b. More specifically, the metering unit 10 writes the response showing the acceptance of the request, to the shared memory 30b through the parallel transmission line 30c (Step S58). Then, the metering unit 10 sends an interruption signal to the communication unit 20 via the interruption line 30e, prompting the communication unit 20 to read the information stored in the shared memory 30b (Step S59).

The communication unit 20 receives the interruption signal sent via the interruption line 30e (Step S60). The communication unit 20 then reads the response from the shared memory 30b (Step S61), and determines that the request has been accepted (Step S62). The communication unit 20 transmits, to the metering unit 10, the updated program provided by the program-updating request source (Step S63). Then, the communication unit 20 sends an interruption signal to the metering unit 10 via the interruption line 30e, prompting the metering unit 10 to read the updated program stored in the shared memory 30b (Step S64).

The metering unit 10 receives the interruption signal sent via the interruption line 30e (Step S65). Then, the metering unit 10 reads the updated program from the shared memory 30b through the parallel transmission line 30c (Step S66), and uses the updated program, updating the program being used at present (Step S67).

The sequence of the second exemplary operation is thus completed.

In the second embodiment, the path 30 is a dedicated path that is dedicated to the data transmission between the connection of the metering unit 10 and communication unit 20, and thus it is possible to transmit a great amount of data at high speed in the parallel transmission scheme. Further, the second embodiment achieves the same advantages as those of the first embodiment.

As has been described, the embodiments can provide a semiconductor device, an electric energy meter and a program, each achieving rightsizing, while maintaining both robustness and availability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a metering unit that operates under control of a first processor to measure electric power consumed;
a communication unit that operates under the control of a second processor different from the first processor to perform communication; and
a path connecting the metering unit and the communication unit.

2. The semiconductor device according to claim 1, wherein the first processor determines whether a request coming from the communication unit satisfies a prescribed condition, and responds to the request when the request satisfies the prescribed condition.

3. The semiconductor device according to claim 2, wherein the first processor records information representing an error in a memory area when the request fails to satisfy the prescribed condition.

4. The semiconductor device according to claim 1, wherein the path is provided with a memory shared by the metering unit and the communication unit; and data is transmitted between the metering unit and the communication unit, by writing and reading the data to and from the memory.

5. The semiconductor device according to claim 1, wherein the metering unit and the communication unit use a common power supply.

6. The semiconductor device according to claim 1, wherein the metering unit, the communication unit and the path are included in an integrated circuit.

7. The semiconductor device according to claim 6, which is one-chip device in which the integrated circuit is sealed in a package.

8. The semiconductor device according to claim 2, wherein the metering unit transmits the data to the communication unit when a request coming from the communication unit satisfies the prescribed condition.

9. The semiconductor device according to claim 2, wherein the metering unit updates a program used by the metering unit when a request coming from the communication unit satisfies the prescribed condition.

10. The semiconductor device according to claim 1, wherein the path includes a transmission line that transmits commands between the metering unit and the communication unit and transmits data between the metering unit and the communication unit.

11. The semiconductor device according to claim 1, wherein the path includes a transmission line that achieves serial transmission of data.

12. The semiconductor device according to claim 1, wherein the path includes a transmission line that achieves parallel transmission of data.

13. The semiconductor device according to claim 4, wherein the path includes an interruption line that transmits an interruption signal prompting a communication partner to read data from the memory, when the data has been written in the memory.

14. The semiconductor device according to claim 1, wherein the metering unit and the communication unit use a common clock signal.

15. An electric energy meter having a semiconductor device, the semiconductor device comprising:
a metering unit that operates under control of a first processor to measure electric power consumed;
a communication unit that operates under the control of a second processor different from the first processor to perform communication; and
a path connecting the metering unit and the communication unit.

16. The electric energy meter according to claim 15, wherein the first processor determines whether a request coming from the communication unit satisfies a prescribed condition, and responds to the request when the request satisfies the prescribed condition.

17. The electric energy meter according to claim 16, wherein the first processor records information representing an error in a memory area when the request fails to satisfy the prescribed condition.

18. The semiconductor device according to claim 1, further comprising:
a first bus connected to the first processor; and
a second bus connected to the second processor, the second bus being different from the first bus.
